(19) United States
(12) Patent Application Publication
(10) Pub. No.: US 2025/0030788 A1
(43) Pub. Date: Jan. 23, 2025

(54) ELECTRONIC DEVICE COMPRISING ROLLABLE DISPLAY, AND METHOD FOR OPERATING SAME

(71) Applicant: SAMSUNG ELECTRONICS CO., LTD., Suwon-si (KR)

(72) Inventors: Bohyeon KIM, Suwon-si (KR); Myunghoon KWAK, Suwon-si (KR); Baekeun CHO, Suwon-si (KR); Junghyeob LEE, Suwon-si (KR); Hyunju HONG, Suwon-si (KR)

(73) Assignee: SAMSUNG ELECTRONICS CO., LTD., Suwon-si (KR)

(21) Appl. No.: 18/906,634

(22) Filed: Oct. 4, 2024

Related U.S. Application Data
(63) Continuation of application No. PCT/KR2023/002074, filed on Feb. 13, 2023.

(30) Foreign Application Priority Data
Apr. 5, 2022 (KR) 10-2022-0042513
Jul. 13, 2022 (KR) 10-2022-0086497

(51) Int. Cl. H04M 1/02; H02J 50/10; H05K 7/20

(52) U.S. Cl. CPC H04M 1/0235; H02J 50/10; H04M 1/0268; H05K 7/2039

(57) ABSTRACT

An electronic device includes: a first housing; a second housing movable with respect to the first housing; a rollable display partially fixed to the second housing and can be inserted into the first housing in a slide-in state or drawn out from the first housing in a slide-out state; a wireless charging IC inside the first housing or the second housing and can receive power from an outside; a battery inside the first housing or the second housing and can be charged with the power received from the outside via the wireless charging IC; and at least one processor configured to: based on the state of the second housing, determine a current to be received from the outside through the wireless charging IC or a current for charging the battery; and transmit a signal related to the current to the wireless charging IC.

### CROSS-REFERENCE TO RELATED APPLICATIONS

This application is a continuation of International Application No. PCT/KR2023/002074, filed on Feb. 13, 2023, which is based on and claims priority to Korean Patent Application 10-2022-0042513, filed on Apr. 5, 2022, in the Korean Intellectual Property Office, and Korean Patent Application 10-2022-0086497, filed on Jul. 13, 2022, in the Korean Intellectual Property Office, the disclosures of which are incorporated by reference herein in their entireties.

### BACKGROUND

### 1. Field

The present disclosure relates to a technology of effectively charging an electronic device including a rollable display.

### 2. Description of the Related Art

The increasing demand for mobile communications has resulted in higher integration of electronic devices, improved portability of electronic devices such as mobile communication terminals, and improved convenience in using multimedia functions. For example, touchscreen function-integrated displays have replaced traditional mechanical (button) keypads, allowing the sizes of electronic devices to be reduce while maintaining the functionality of input devices. For example, removal of mechanical keypads from electronic devices may improve the portability of the electronic devices. Furthermore, in a case where a display is extended to an area from which a mechanical keypad is removed, an electronic device including touchscreen functionality may provide a larger screen than an electronic device including a mechanical keypad, even if the electronic device has a size and weight identical to those of the electronic device including the mechanical keypad.

When surfing the web or using multimedia functions, it may be more convenience to use an electronic device outputting a large screen. A larger display may be mounted on the electronic device to output a larger screen, but considering the portability of the electronic device, there may be limitations in expanding the size of the display. In various embodiments, the display using an organic light-emitting diode may secure the portability of the electronic device while providing a large screen. For example, the display using an organic light-emitting diode (or the electronic device including same) may realize stable operations even when manufactured to be remarkably thin and may be mounted on the electronic device in a foldable or bendable shape or a rollable shape.

A conventional bar-type electronic device performs charging by varying a current depending on a charging state and, specifically in a case where the temperature of the electronic device rises due to charging or other reasons, reduces a charging current or stops the charging to secure battery safety and improve user usability, so as to enter heat limitation control for inducing a decrease in the temperature of the electronic device. Meanwhile, when entering the heat limitation control, a charging current for a battery is reduced or the charging of the battery is stopped, causing a problem that charging efficiency is drastically reduced.

### SUMMARY

Provided is an electronic device including a rollable display having a different heat dissipation coefficient depending on an extended state or reduced state, compared to a conventional bar-type electronic device having a constant dissipation coefficient. According the electronic device may be efficiently charged no matter the state of the electronic device.

According to an aspect of the disclosure, an electronic device includes: a first housing; a second housing movable with respect to the first housing; a rollable display at least partially fixed to the second housing and configured to be inserted into an inside of the first housing in a slide-in state of the second housing or drawn out from the inside of the first housing in a slide-out state of the second housing; a wireless charging integrated circuit (“IC”) in the first housing or the second housing and configured to be capable of receiving power from an outside; a battery in the first housing or the second housing and configured to be charged with power received from the outside through the wireless charging IC; and at least one processor is configured to: based on the slide-in state or the slide-out state of the second housing with respect to the first housing, determine an amount of a current to be received from the outside through the wireless charging IC or an amount of a current for charging the battery, wherein the current to be received from the outside through the wireless charging IC is different from the current for charging the battery; and transmit a signal related to the current to be received from the outside through the wireless charging IC or the current for charging the battery to the wireless charging IC.

The electronic device may further include an antenna electrically connected to the wireless charging IC and may be configured to wirelessly receive power. The wireless charging IC may be further configured to wirelessly receive power through the antenna.

The at least one processor is may be further configured to: determine an upper limit current value of the amount of the current to be received from outside through the wireless charging IC or the amount of the current for charging the battery; and transmit a signal related to the upper limit current value to the wireless charging IC.

In a state in which the second housing is in the slide-in state with respect to the first housing, the amount of the current to be received from outside through the wireless charging IC or the amount of the current for charging the battery may be a first current. In a state in which the second housing is in the slide-out state with respect to the first housing, the amount of the current to be received from outside through the wireless charging IC or the amount of the current for charging the battery may be a second current. The amount of the first current may be less than the amount of the second current.

The electronic device may further include a temperature sensor inside the first housing or the second housing and may be configured to sense an internal temperature of the electronic device or a temperature of the battery. The at least one processor may be further configured to: acquire a signal related to the internal temperature of the electronic device or the temperature of the battery from the temperature sensor; and based on the acquired signal related to the internal temperature of the electronic device or the temperature of the battery and the slide-in state or the slide-out state of the second housing with respect to the first housing, determine the current to be received from the outside through the wireless charging IC or the current for charging the battery.

In a state in which the internal temperature of the electronic device or the temperature of the battery is equal to or greater than a preconfigured first temperature and less than a preconfigured second temperature, the at least one processor may be further configured to configure the amount of the current to be received from outside through the wireless charging IC or the amount of the current for charging the battery to have a first current or a second current based on the slide-in state or the slide-out state of the second housing with respect to the first housing. The amount of the first current may be less than the amount of the second current.

In a state in which the internal temperature of the electronic device or the temperature of the battery is less than the preconfigured first temperature, the at least one processor may be further configured to configure the current to be received from outside through the wireless charging IC or the current for charging the battery to be the second current.

In a state in which the internal temperature of the electronic device or the temperature of the battery is equal to or greater than the preconfigured second temperature, the at least one processor may be further configured to configure the current to be received from outside through the wireless charging IC or the current for charging the battery to be the first current.

The electronic device may further include a temperature sensor inside the first housing or the second housing and may be configured to sense an internal temperature of the electronic device or a temperature of the battery. The at least one processor may be further configured to: acquire a signal related to the internal temperature of the electronic device or the temperature of the battery from the temperature sensor; and provide, to a user, a notification suggesting a change of the slide-in state or the slide-out state of the second housing with respect to the first housing based on the signal related to the internal temperature of the electronic device or the temperature of the battery.

In a state in which the second housing is in the slide-in state with respect to the first housing, the at least one processor may be further configured to provide a notification suggesting the user to change the second housing from the slide-in state to the slide-out state respect to the first housing.

In a state in which the second housing is in the slide-in state with respect to the first housing, the at least one processor may be further configured to: configure the amount of the current to be received from outside through the wireless charging IC or the current for charging the battery to be a first current; compare an amount of the first current with an amount of a second current being the amount of the current to be received from outside through the wireless charging IC or the amount of the current for charging the battery when the second housing is changed from the slide-in state to the slide-out state with respect to the first housing; and provide the notification suggesting the user to change the second housing from the slide-in state to the slide-out state with respect to the first housing, based on a comparison result of the amount of the first current and the amount of the second current.

The electronic device may further include a drive module which may be configured to generate drive power for movement between the first housing and the second housing. The at least one processor may be further configured to, in a state in which a signal related to the reception of power from outside is acquired, transmit, to the drive module, a drive signal which may be configured to change the second housing from the slide-in state to the slide-out state with respect to the first housing or change the second housing from the slide-out state to the slide-in state with respect to the first housing.

The battery may be inside the second housing, and the electronic device may further include a heat dissipation plate extending in a planar direction and disposed between the antenna and the battery. The heat dissipation plate may be bent and extended in a direction intersecting the planar direction and contacting at least two surfaces of the second housing.

According to another aspect of the disclosure, a method for operating an electronic device including a first housing, a second housing movable with respect to the first housing, a rollable display partially fixed to the second housing and configured to be inserted into an inside of the first housing in a slide-in state of the second housing or drawn out from the inside of the first housing in a slide-out state of the second housing, a wireless charging IC configured to be capable of receiving power from an outside, and a battery configured to be charged with at least a portion of power received through the wireless charging IC, the method includes: based on the slide-in state or the slide-out state of the second housing with respect to the first housing, determining an amount of a current to be received from the outside through the wireless charging IC or an amount of a current for charging the battery, wherein the current to be received from the outside through the wireless charging IC is different from the current for charging the battery; and transmitting a signal related to the current to be received from the outside through the wireless charging IC or the current for charging the battery to the wireless charging IC.

The method may further include acquiring a signal related to an internal temperature of the electronic device or a temperature of the battery from a temperature sensor. The determining of the amount of the current to be received from outside through the wireless charging IC or the amount of the current for charging the battery may be based on the acquired signal related to the internal temperature of the electronic device or the temperature of the battery and the slide-in state or the slide-out state of the second housing with respect to the first housing.

According to the electronic device and the method for operating the electronic device according to an embodiment of the disclosure, by adjusting a charging current of the electronic device according to the arrangement state between the first housing and the second housing, the charging efficiency and charging speed of the electronic device may be improved.

Furthermore, according to the electronic device and the method for operating the electronic device according to an embodiment of the disclosure, by inducing the arrangement state between the first housing and the second housing to be changed when charging the electronic device, the heat generation of the electronic device may be prevented and the charging speed may be improved.

### BRIEF DESCRIPTION OF THE DRAWINGS

Additional aspects will be set forth in part in the description which follows and, in part, will be apparent from the description, or may be learned by practice of the presented embodiments.

FIG. 1 is a block view illustrating an electronic device in a network environment according to an embodiment of the disclosure.

FIG. 2A is a view illustrating a state in which a second display area of a display is received in a housing according to an embodiment of the disclosure.

FIG. 2B is a view illustrating a state in which a second display area of a display is exposed to outside of a housing according to an embodiment of the disclosure.

FIG. 3A is an exploded perspective view of an electronic device according to an embodiment of the disclosure.

FIG. 3B is a sectional view taken along line A-A′ of FIG. 2A according to an embodiment of the disclosure.

FIG. 3C is a sectional view taken along line B-B′ of FIG. 2B according to an embodiment of the disclosure.

FIG. 4 is a view illustrating an internal space between a reduced state and an extended state of an electronic device including a rollable display according to an embodiment of the disclosure.

FIG. 5 is a block view illustrating an electronic device including a rollable display according to an embodiment of the disclosure.

FIG. 6 is a flowchart illustrating a method for operating an electronic device including a rollable display according to an embodiment of the disclosure.

FIG. 7 is a flowchart illustrating a method for configuring a upper limit current value of an electronic device including a rollable display according to an embodiment of the disclosure.

FIG. 8 is a view illustrating an operation of providing a notification and changing an extended state of an electronic device including a rollable display according to an embodiment of the disclosure.

FIG. 9 is a view illustrating an electronic device including a rollable display having a heat dissipation plate according to an embodiment of the disclosure.

FIG. 10 is an exploded perspective view illustrating an electronic device including a rollable display having a heat dissipation plate according to an embodiment of the disclosure.

### DETAILED DESCRIPTION

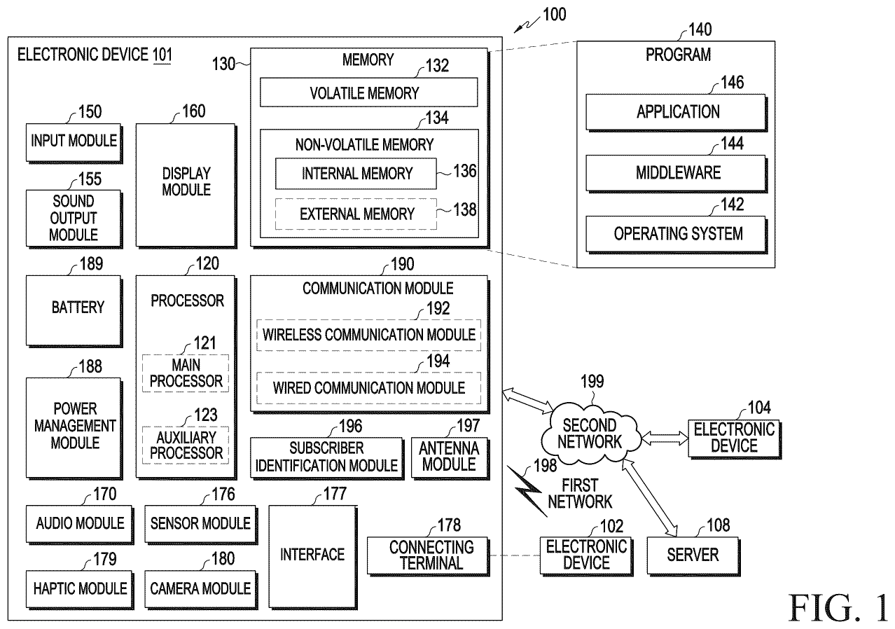

FIG. 1 is a block diagram illustrating an electronic device 101 in a network environment 100 according to an embodiment. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to an embodiment may be one of various types of electronic devices. The electronic devices may include, for example, a portable communication device (e.g., a smartphone), a computer device, a portable multimedia device, a portable medical device, a camera, an electronic device, or a home appliance. According to an embodiment of the disclosure, the electronic devices are not limited to those described above.

It should be appreciated that an embodiment of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with an embodiment of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

An embodiment as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to an embodiment of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities, and some of the multiple entities may be separately disposed in different components. According to an embodiment, one or more of the above-described components may be omitted, or one or more other components may be added. Alternatively or additionally, a plurality of components (e.g., modules or programs) may be integrated into a single component. In such a case, according to an embodiment, the integrated component may still perform one or more functions of each of the plurality of components in the same or similar manner as they are performed by a corresponding one of the plurality of components before the integration. According to an embodiment, operations performed by the module, the program, or another component may be carried out sequentially, in parallel, repeatedly, or heuristically, or one or more of the operations may be executed in a different order or omitted, or one or more other operations may be added.

Hereinafter, various embodiment of an electronic device 200 (e.g., the electronic device 101) to be described herein will be shown.

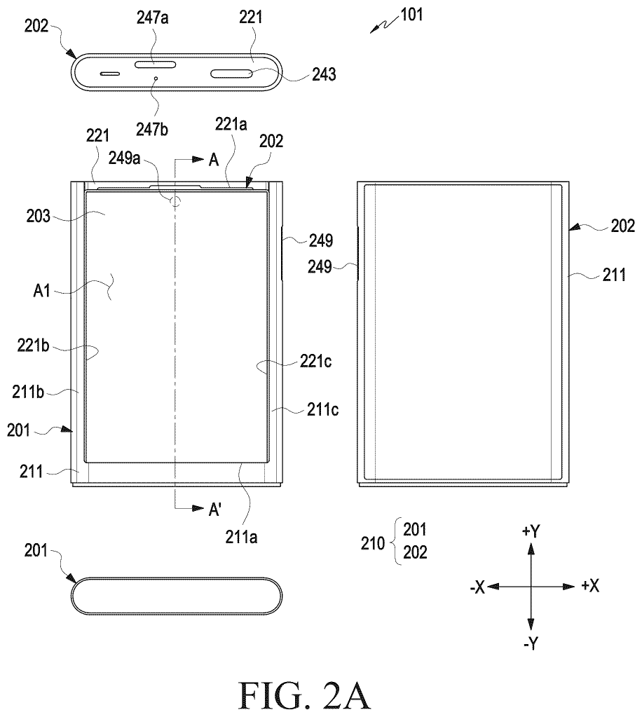

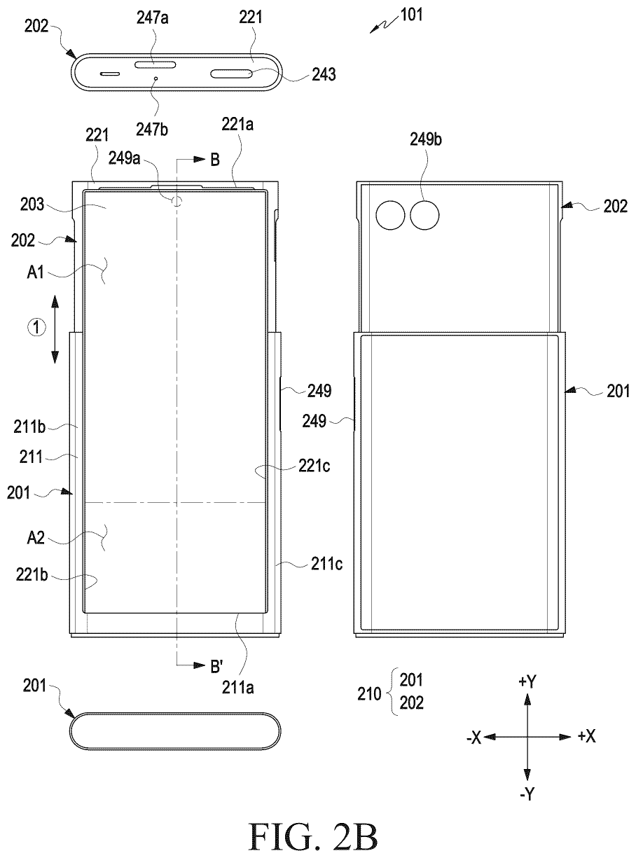

FIG. 2A is a view illustrating a state in which a second display area of a display is received in a housing according to an embodiment of the disclosure. FIG. 2B is a view illustrating a state in which a second display area of a display is exposed to outside of a housing according to an embodiment of the disclosure.

FIGS. 2A and 2B illustrates a structure in which a display 203 (e.g., a foldable display or a rollable display) is extended in a longitudinal direction (e.g., the +Y direction) when viewed from the front of the electronic device 101. However, the extension direction of the display 203 is not limited to one direction (e.g., the +Y direction). For example, The display 203 may be designed to extend in an upward direction (e.g., the +Y direction), a rightward direction (e.g., the +X direction), a leftward direction (e.g., the −X direction), and/or a downward direction (e.g., the −Y direction).

The state shown in FIG. 2A may be referred to as a closed state of the electronic device 101 or the housing 210 and a slide-in state of the display 203.

The state shown in FIG. 2B may be referred to as an open state of the electronic device 101 or the housing 210 and a slide-out state of the display 203.

Referring to FIGS. 2A and 2B, the electronic device 101 may include the housing 210. The housing 210 may include a first housing 202 and a second housing 202 disposed to be movable with respect to the first housing 201. In various embodiment, it may be comprehended as a structure that the first housing 201 is slidably disposed on the second structure 202 in the electronic device 101. According to an embodiment, the second housing 202 may be disposed to be capable of reciprocating by a predetermined distance in a direction, for example, a direction indicated by arrow \textcircled{1}, based on the first housing 201.

According to an embodiment, the second housing 202 may be referred to as a slide part or a slide housing, and may relatively move with respect to the first housing 201. According to an embodiment, the second housing 202 may receive various electrical and electronic components including a printed circuit board or a battery.

According to an embodiment, in the first housing 202, a motor, a speaker, a SIM socket, and/or a sub-printed circuit board electrically connected to a main printed circuit board may be disposed. The second housing 201 may receive the main circuit board on which electrical components, such as an application processor and a communication processor, are mounted.

According to an embodiment, the first housing 201 may include a first cover member 211 (e.g., a main case). The first cover member 211 may include a (1-1)th lateral wall 211a, a (1-2)th lateral wall 211b extending from the (1-1)th lateral wall 211a, and a (1-3)th lateral wall 211c extending from the (1-1)th lateral wall 211a and substantially perpendicular to the (1-2)th lateral wall 211b. According to an embodiment, the (1-2)th lateral wall 211b and the (1-3)th lateral wall 211c may be disposed to be substantially perpendicular to the (1-1)th lateral wall 211a.

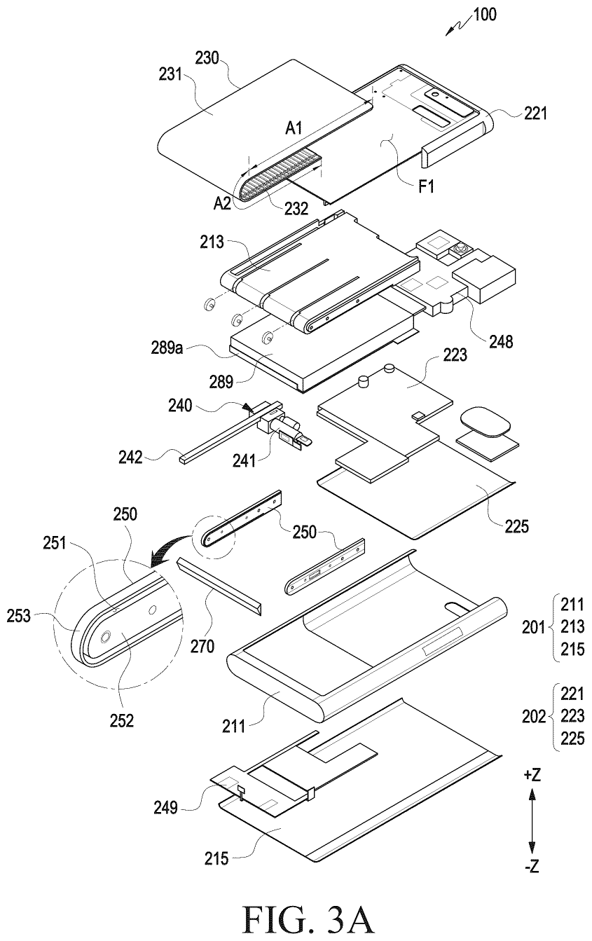

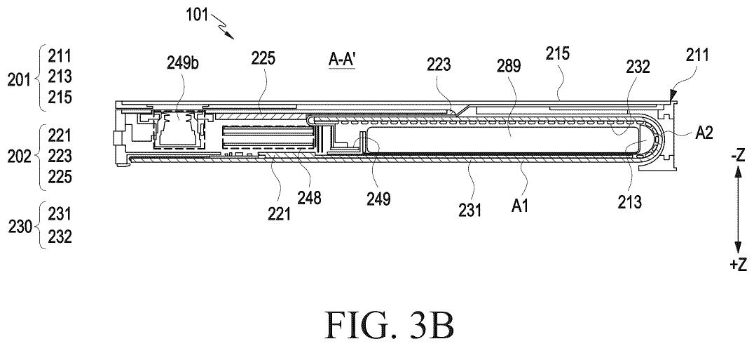

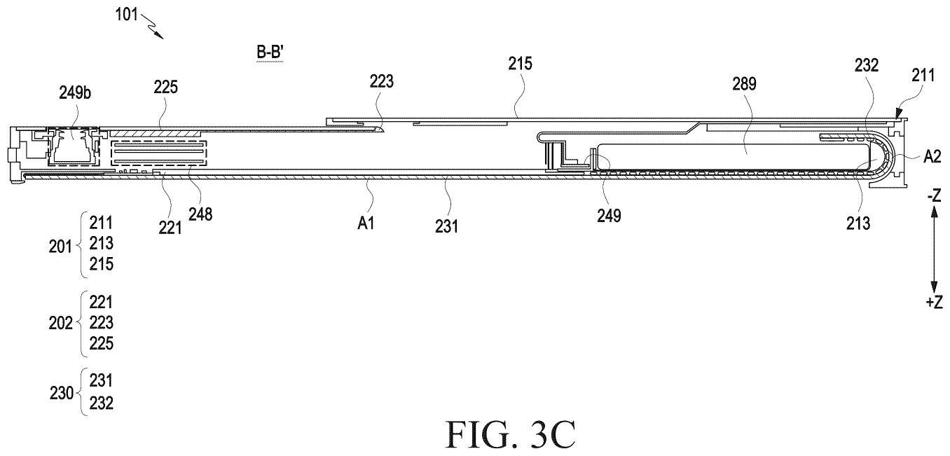

According to an embodiment, the (1-1)th lateral wall 211a, the (1-2)th lateral wall 211b, and the (1-3)th lateral wall 211c of the first cover member 211 may be configured to be open at one side (e.g., a front surface) so as to receive (or surround) at least a portion of the second housing 202. For example, at least a portion of the second housing 202 may be surrounded with respect to the first housing 201 and may slide in a direction parallel to a first surface (e.g., the first surface F1 in FIG. 3A), for example, in a direction indicated by arrow \textcircled{1} while being guided by the first housing 201. According to an embodiment, the (1-1)th lateral wall 211a, the (1-2)th lateral wall 211b, and/or the (1-3)th lateral wall 211c of the first cover member 211 may be integrally configured. According to an embodiment, the (1-1)th lateral wall 211a, the (1-2)th lateral wall 211b, and/or the (1-3)th lateral wall 211c of the first cover member 211 may be configured as separate structures and joined or assembled.

According to an embodiment, the first cover member 211 may be configured to surround at least a portion of the display 203. For example, at least a portion of the display 203 may be configured to be surrounded by the (1-1)th lateral wall 211a, the (1-2)th lateral wall 211b, and/or the (1-3)th lateral wall 211c of the first cover member 211.

According to an embodiment, the second housing 202 may include a second cover member 221 (e.g., a slide plate). The second cover member 221 may include a first surface (e.g., the first surface F1 in FIG. 3A) having a plate shape and supporting internal components. For example, the second cover member 221 may support at least a portion (e.g., a first display area A1) of the display 203. According to an embodiment, the second cover member 221 may be referred to as a front cover.

According to an embodiment, the second cover member 221 may include a (2-1)th lateral wall 221a, a (2-2)th lateral wall 221b extending from the (2-1)th lateral wall 221a, and a (2-3)th lateral wall 221c extending from the (2-1)th lateral wall 221a and substantially perpendicular to the (2-2)th lateral wall 221b. According to an embodiment, the (2-2)th lateral wall 221b and the (2-3)th lateral wall 221c may be disposed to be substantially perpendicular to the (2-1)th lateral wall 221a.

According to an embodiment, the second housing 202 may move in a first direction (e.g., direction \textcircled{1} parallel to the (1-2)th lateral wall 211b or the (1-2)th lateral wall 211c to configure the open state and the closed state of the housing 210. In the closed state, the second housing 202 may be located at a position corresponding to a value from the (1-1)th lateral wall 211a and the second housing 202 may be moved to be located a second distance greater than the value from the (1-1)th lateral wall. In some embodiments, in the closed state, the first housing 201 may surround a portion of the (2-1)th lateral wall 221a.

According to an embodiment, the electronic device 101 may include a display 203, a key input device 245, a connector hole 243, an audio module 247a or 247b, or a camera module 249a or 249b. According to an embodiment, the electronic device 101 may further include an indicator (e.g., an LED device) or various sensor modules.

According to an embodiment, the display 203 may include a first display area A1 and a second display area A2 configured to be exposed to outside of the electronic device 101, based on sliding of the second housing 202. According to an embodiment, the first display area A1 may be disposed on the second housing 202. For example, the first display area A1 may be disposed on the second cover member 221 of the second housing 202. According to an embodiment, the second display area A2 may extend from the first display area A1 and, when the second housing 202 slides with respect to the first housing 201, may be received (e.g., the slide-in state) inside the first housing 201 or visually exposed (e.g., the slide-out state) outside the electronic device 101.

According to an embodiment, the second display area A2 may be moved while being substantially guided by an area (e.g., the curved surface 213a in FIG. 3A) of the first housing 201 and may be received in a space located inside the first housing 201 or exposed outside the electronic device 101. According to an embodiment, the second display area A2 may move based on sliding in a first direction (e.g., the direction indicated by arrow \textcircled{1} of the second housing 202. For example, while the second structure 202 slides, a portion of the second display area A2 may be transformed to have a curved shape at a location corresponding to the curved surface 213a of the first housing 201.

According to an embodiment, when viewed from the upper portion of the second cover member 221 (e.g., a front cover), in a case where the housing 210 changes from the closed state to the open state (e.g., in a case where the second housing 202 slides to the first housing 201 to be extended), the second display area A2 may be gradually exposed to outside of the first housing 201 and configure a substantially flat surface together with the first display area A1. According to an embodiment, the display 203 may be combined to or disposed adjacent to a touch sensing circuit, a pressure sensor for measuring a strength (pressure) of a touch, and/or a digitizer for detecting a magnetic field-type stylus pen. According to an embodiment, regardless of the closed state or the open state of the housing 210, an exposed portion of the second display area A2 may be located on a portion (e.g., the curved surface 213a in FIG. 3A) of the first housing and the portion of the second display area A2 may maintain a curved shape at the location corresponding to the curved surface 213a.

According to an embodiment, the key input device 245 may be disposed on an area of the first housing 201. Depending on the appearance or use state, the electronic device 101 may be designed to omit the described key input device 245 or to further include one or more key input devices. According to an embodiment, the electronic device 101 may include a key input device not described above, for example, a home key button or a touch pad disposed around the home key button. According to an embodiment, at least a portion of the key input device 245 may be disposed on the (1-1)th lateral wall 211a, the (1-2)th lateral wall 211b, and/or the (1-3)th lateral wall 211c of the first cover member 201.

According to an embodiment, the connector hole 243 may be omitted depending on an embodiment, and may include a connector (e.g., a USB connector) for transmitting or receiving power or data to or from an external electronic device. According to an embodiment, the electronic device 101 may include multiple connector holes 243, and a portion of the multiple connector holes 243 may function as a connector hole for transmitting or receiving an audio signal to or from an external electronic device. In an embodiment described, although the connector hole 243 is located in the second housing 202, without limitation thereto, the connector hole 243 or a connector hole not shown in the drawing may be located in the first housing 201.

According to an embodiment, the audio module 247a or 247b may include at least one speaker hole 247a or at least one microphone hole 247b. One of the speaker hole 247a may be provided as a receiver hole for calling and another one may be provided as an external speaker hole. The electronic device 101 may include a microphone for acquiring a sound and the microphone may acquire a sound from outside of the electronic device 101 through the microphone hole 247b. According to an embodiment, the electronic device 101 may include multiple microphones to detect a direction of a sound. According to an embodiment, the electronic device 101 may include an audio module in which the speaker hole 247a and the microphone hole 247b is realized in one hole, or include a speaker excluding the speaker hole 247a (e.g., a piezo speaker).

According to an embodiment, the camera module 249a or 249b may include a first camera module 249a (e.g., a front camera) and a second camera module 249b (e.g., a rear camera) (e.g., the second camera module 249b in FIGS. 3B and 3C). According to an embodiment, the electronic device 101 may include at least one of a wide angle camera, a telephoto camera, or a close-up camera, and may include, according to an embodiment, an infrared projector and/or an infrared receiver to measure a distance to a subject. The camera modules 249a or 249b may include one or more of lenses, an image sensor, and/or an image signal processor. The first camera module 249a may be disposed to face a direction as the display 203. For example, the first camera module 249a may be disposed on an area around the first display area A1 or overlapping the display 203 and in a case where the first camera module is disposed at an area overlapping the display 203, may photograph a subject through the first display area 203. According to an embodiment, the first camera module 249a may include a screen display area (e.g., the first display area A1) not exposed visually and may include a hidden display rear camera (under display camera (UDC)). According to an embodiment, the second camera module 249b may photograph a subject in a direction opposite to the first display area A1. According to an embodiment, the first display module 249a and/or the second camera module 249b may be disposed on the second housing 202.

According to an embodiment, an indicator of the electronic device 101 may be disposed on the first housing 201 or the second housing 202 and may include a light-emitting diode to provide state information of the electronic device 101 in a form of visual signal. The sensor module of the electronic device 101 may generate an electrical signal or a data value corresponding to an internal operation state or external environment state of the electronic device 101. The sensor module may include, for example, a proximity sensor, a fingerprint sensor, or a biosensor (for example, an iris/face recognition sensor or an HRM sensor). In another embodiment, the sensor module may further include at least one from among, for example, a gesture sensor, a gyro sensor, an air pressure sensor, a magnetic sensor, an acceleration sensor, a grip sensor, a color sensor, an infrared (IR) sensor, a temperature sensor, a humidity sensor, or an illuminance sensor.

FIG. 3A is an exploded perspective view of an electronic device according to an embodiment of the disclosure.

FIG. 3B is a sectional view taken along line A-A′ of FIG. 2A according to an embodiment of the disclosure.

FIG. 3C is a sectional view taken along line B-B′ of FIG. 2B according to an embodiment of the disclosure.

Referring to FIG. 3A, 3B, and/or 3C, the electronic device 101 may include a first housing 201, a second housing 202, a display assembly 230, and a drive structure 240. The configuration of the first housing 201, the second housing 202, and the display assembly 230 of FIG. 3A, 3B, and/or 3C may be entirely or partially identical to that of the first housing 201, the second housing 202, and the display 203 of FIG. 2A and/or 2B.

According to an embodiment, the first housing 201 may include a first cover member 211 (e.g., the first cover member 211 in FIGS. 2A and 2B), a frame 213, and a first rear plate 215.

According to an embodiment, the first cover member 211 may receive at least a portion of the frame 213 and receive a component (e.g., the battery 289) located on the frame 213. According to an embodiment, the first cover member 211 may be configured to surround at least a portion of the second housing 202. According to an embodiment, a second circuit board 249 configured to receive an electronic component (e.g., the processor 120 and/or the memory 130 in FIG. 1) may be connected to the first cover member 211.

According to an embodiment, the frame 213 may be connected to the first cover member 211. For example, the frame 213 may be connected to the first cover member 211 and the second housing 202 may relatively move with respect to the first cover member 211 and/or the frame 213. According to an embodiment, the frame 213 may receive a battery 289. According to an embodiment, the frame 213 may include a curved surface part 213a facing the display assembly 230.

According to an embodiment, the first rear plate 215 may substantially configure at least a portion of an exterior of the first housing 201 or the electronic device 101. For example, the first rear plate 215 may be coupled to an external surface of the first cover member 221. According to an embodiment, the first rear plate 215 may provide a decorative effect to the appearance of the electronic device 101. The first rear plate 215 may be manufactured using at least one of a metal, glass, a synthetic resin, or ceramic.

According to an embodiment, the second housing 202 may include a second cover member 221 (e.g., the second cover member 221 in FIGS. 2A and 2B), a rear cover 223, and a second rear plate 225.

According to an embodiment, the second cover member 221 may be connected to the first housing 201 through a guide rail 250 and reciprocate in one direction (e.g., the direction indicated by arrow \textcircled{1} in FIG. 2B) while being guiding by the guide rail 250.

According to an embodiment, the second cover member 221 may support at least a portion of the display 203. For example, the second cover member 221 may include a first surface F1, and the first display area A1 of the display 203 may be substantially located on the first surface F1 to be maintained in a planar shape. According to an embodiment, the second cover member 221 may be made of a metal and/or non-metal material (e.g., polymer). According to an embodiment, a first circuit board 248 configured to receive an electronic component (e.g., the processor 120 and/or the memory 130 in FIG. 1) may be connected to the second cover member 221.

According to an embodiment, the rear cover 223 may protect a component (e.g., the first circuit board 248) located on the second cover member 221. For example, the rear cover 223 may be connected to the second cover member 221 and configured to surround at least a portion of the first circuit board 248. According to an embodiment, the rear cover 223 may include an antenna pattern for communication with an external electronic device. For example, the rear cover 223 may include a laser direct structuring (LDS) antenna.

According to an embodiment, the second rear plate 225 may substantially configure at least a portion of an exterior of the second housing 202 or the electronic device 101. For example, the second rear plate 225 may be coupled to an external surface of the second cover member 221. According to an embodiment, the second rear plate 225 may provide a decorative effect to the appearance of the electronic device 101. The second rear plate 215 may be manufactured using at least one of a metal, glass, a synthetic resin, or ceramic.

According to an embodiment, the display assembly 230 may include a display 231 (e.g., the display 203 in FIGS. 2A and 2B) and a multi-bar structure 232 supporting the display 203. According to an embodiment, the display 231 may be referred to as a rollable display, a foldable display, and/or a rollable display.

According to an embodiment, the multi-bar structure 232 may be connected or attached to at least a portion (e.g., the second display area A2) of the display 231. According to an embodiment, when the second housing 202 slides, the multi-bar structure 232 may move with respect to the first housing 201. In the closed state (e.g., FIG. 2A) of the electronic device 101, the multi-bar structure 232 may be mostly received in the first housing 201 and located between the first cover member 211 and the second cover member 221. According to an embodiment, at least a portion of the multi-bar structure 232 may move in response to the curved surface 213a located at an edge of the frame 213. According to an embodiment, the multi-bar structure 232 may be referred to as a display support member or a support structure and may have a single plate shape.

According to an embodiment, the drive structure 240 may relatively move the second housing 202 with respect to the first housing 201. For example, the drive structure 240 may include a motor 241 configured to generate drive power for sliding of the housing 201 or 202. The drive structure 240 may include a gear (e.g., a pinion) connected to the motor 241 and a rack 242 configured to be engaged to the gear.

According to an embodiment, the housing in which the rack 242 is located and the housing in which the motor 241 is located may be different. According to an embodiment, the motor 241 may be connected to the second housing 202 and the rack 242 may be connected to the first housing 201. According to another embodiment, the motor 241 may be connected to the first housing 201 and the rack 242 may be connected to the second housing 202.

According to an embodiment, the first housing 201 may receive a first circuit board 248 (e.g., a main board). According to an embodiment, a processor, a memory, and/or an interface may be mounted on the first circuit board 248. The processor may include one or more of, for example, a central processing unit, an application processor, a graphic processing unit, an image signal processor, a sensor herb processor, or a communication processor. According to an embodiment, the first circuit board 248 may include a flexible printed circuit board type radio frequency cable (FRC). The first circuit board 248 may be disposed on at least a portion of the second cover member 221 and electrically connected to an antenna module and a communication module.

According to an embodiment, the memory may include, for example, a volatile memory or a nonvolatile memory.

According to an embodiment, the interface may include, for example, a high-definition multimedia interface (HDMI), a universal serial bus (USB) interface, an SD card interface, and/or an audio interface. The interface, for example, may electrically or physically connect the electronic device 101 to an external electronic device, and may include a USB connector, an SD card/MMC connector, or an audio connector.

According to an embodiment, the electronic device 101 may include a second circuit board 249 (e.g., a sub-circuit board) spaced apart from the first circuit board 248 (e.g., a main circuit board) within the first housing 201. The second circuit board 249 may be electrically connected to the first circuit board 248 through a connection flexible board. The second circuit board 249 may be electrically connected to an electrical component disposed at an end area of the electronic device 101, such as the battery 289 or a speaker and/or SIM socket, to transfer a signal and power. According to an embodiment, the second circuit board 249 may receive a wireless charging antenna (e.g., a coil). For example, the battery 289 may receive power from an external electronic device by using the wireless charging antenna. For another example, the battery 289 may transfer power to an external electronic device by using the wireless charging antenna.

According to an embodiment, the battery 289 corresponds to a device for supplying power to at least one component of the electronic device 101, and may include a non-rechargeable primary battery, or a rechargeable secondary battery, or a fuel cell. The battery 289 may be disposed and integrally configured in the electronic device 101 or may be disposed to be attachable to/detachable from the electronic device 101. According to an embodiment, the battery 289 may be configured as a single integrated battery or may include multiple separate batteries. According to an embodiment, the battery 289 may located on the frame 213 and the battery 289 and the frame 213 may slide and move together.

According to an embodiment, the guide rail 250 may guide movement of the multi-bar structure 232. For example, the multi-bar structure 232 may slide and move along a slit 251 configured on the guide rail 250. According to an embodiment, the guide rail 250 may be connected to the first housing 201. For example, the guide rail 250 may be connected to the first cover member 211 and/or the frame 213. According to an embodiment, the slit 251 may be referred to as a groove or recess configured on an internal surface of the guide rail 250.

According to an embodiment, the guide rail 250 may provide pressure to the multi-bar structure 233, based on driving of the motor 241.

According to an embodiment, when the electronic device 101 is changed from the closed state to the open state, an internal portion 252 of the guide rail 250 may provide pressure to the multi-bar structure 232. The multi-bar structure 232 having received the pressure may move along the slit 251 of the guide rail 250, and the second housing 202 may be changed from the slide-in state to the slide-out state with respect to the first housing 201. At least a portion of the display assembly 230 having been received between the first cover member 211 and the frame 213 may be extended to the front surface.

According to an embodiment, when the electronic device 101 is changed from the open state to the closed state, an outer portion 253 of the guide rail 250 may provide pressure to the bent multi-bar structure 232. The multi-bar structure 232 having received the pressure may move along the slit 251 of the guide rail 250, and the second housing 202 may be changed from the slide-out state to the slide-in state with respect to the first housing 201. At least a portion of the display assembly 230 may be received between the first cover member 211 and the frame 213.

Referring to FIG. 3B, in a case where the electronic device 101 is in the closed state, at least a portion of the second housing 202 may be disposed to be received in the first housing 201. As the second housing 202 is received in the first housing 201, the overall volume of the electronic device 101 may be reduced. According to an embodiment, in a case where the second housing 202 is received in the first housing 201, the size of the display 231 visually exposed may be minimized. For example, in a case where the second housing 202 is completely received in the first housing 201, the first display area A1 of the display 231 may be visually exposed and the second display area A2 may not visually exposed. At least a portion of the second display area A2 may be disposed between the battery 289 and the rear plate 215 or 225.

Referring to FIG. 3C, in a case where the electronic device 101 is in the open state, at least a portion of the second housing 202 may protrude from the first housing 201. As the second housing 202 protrudes from the first housing 201, the overall volume of the electronic device 101 may increase. According to an embodiment, in a case where the second housing 202 protrudes from the first housing 201, at least a portion of the second display area A2 of the display 231 may be visually exposed to outside of the electronic device 101 together with the first display area A1.

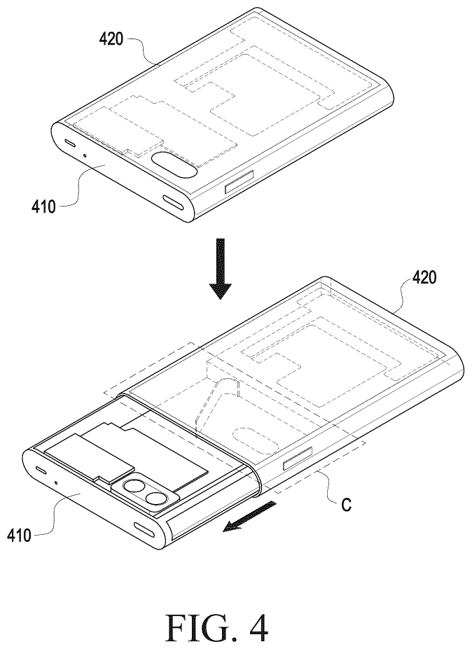

FIG. 4 is a view illustrating an internal space C between a reduced state and an extended state of an electronic device including a rollable display according to an embodiment of the disclosure.

Referring to FIG. 4, the electronic device including a rollable display according to various embodiment may include a vertical slidable type in which a first housing 410 and a second housing 420 slide in the vertical direction as one embodiment and a horizontal slidable type in which the housings slide in the horizontal direction as another embodiment. The vertical slidable-type electronic device according to an embodiment may be extended in the vertical direction when the rollable display is unrolled.

When the slidable-type electronic device according to an embodiment extends according to movement of the first housing 410 and the second housing 420, components disposed inside may move, generating an internal space C. Accordingly, heat generated from the components disposed inside the first housing 410 or the second housing 420 is dissipated through the empty internal space C, and thus the slidable-type electronic device may have a difference in heat dissipation performance between an extended state and a reduced state.

The electronic device including the rollable display according to an embodiment may include a drive module (e.g., a drive motor) configured to generate drive power for moving the second housing 420 based on the first housing 410 and thus an additional heat source may be generated. Specifically, the electronic device including the rollable display according to an embodiment may experience a difficulty in dissipating heat because more heat sources are concentrated in a reduced space compared to a conventional bar type in a reduced state. However, in order to efficiently charge an electronic device, the electronic device or internal components thereof need to be maintained at an appropriate temperature and prevented from entering heat limitation control due to heat generation during charging.

The electronic device including the rollable display according to an embodiment may have lower dissipation performance in the reduced state (i.e. slide-in state) compared to the extended state (i.e. slide-out state) and when the battery is charged with a charging current identical to that in the extended state, an internal temperature rises at a relatively fast rate and the electronic device may enter the heat limitation control.

To prevent the aforementioned problem, depending on the arrangement state of the electronic device including the rollable display, a charging current of the battery needs to be varied to ensure efficient charging by minimizing the possibility of entering the heat limitation control in the reduced state (i.e. slide-in state).

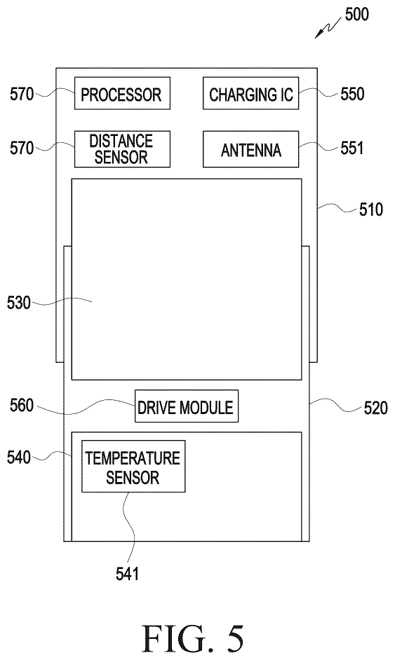

FIG. 5 is a block view illustrating an electronic device 500 including a rollable display 530 according to an embodiment of the disclosure.

Referring to FIG. 5, the electronic device 500 including the rollable display 530 according to an embodiment may include a first housing 510, a second housing 520 disposed to be relatively movable with respect to the first housing 510 and overlapping with at least a portion of the first housing 510, and the rollable display 530 which is at least partially fixed (mounted) to a surface of the second housing 520, at least partially exposed to outside of the electronic device 500, and has at least a portion inserted into the first housing 510, based on the second housing 520 moving in a first direction with respect to the first housing 510 or drawn out from the inside of the first housing 510 based on the second housing 520 moving in a second direction with respect to the first housing 510.

In the electronic device 500 including the rollable display 530 according to an embodiment, the first housing 510 and the second housing 520 may be coupled to each other to be relatively movable, and one end of the rollable display 530 may be fixed to the second housing 520 so that as the second housing 520 moves with respect to the first housing 510, an area exposed to an outside may vary. In an embodiment, in a case where the second housing 520 moves in a first direction with respect to the first housing 510, at least a portion of the rollable display 530 may be inserted into an inside of the first housing 510 to reduce an exposed area (slide-in) and alternatively, in a case where the second housing 520 moves in a second direction with respect to the first housing 510, at least a portion of the rollable display 530 is drawn out from the inside of the first housing 510 to extend the exposed area (slide-out).

In the electronic device 500 including the rollable display 530 according to an embodiment, the arrangement state between the first housing 510 and the second housing 520 may include at least one among a first state (e.g., the reduced state or slide-in state) in which the second housing 520 moves in the first direction with respect to the first housing 510 so that at least a portion of the rollable display 530 is inserted into the first housing 510 or a second state (e.g., the extended state or slide-out state) in which the second housing 520 moves in the second direction with respect to the first housing 510 so that at least a portion of the rollable display 530 is drawn out from the inside of the first housing 510. Here, the first state may correspond to a reduced state in which the first housing 510 and the second housing 520 are disposed in a direction to be adjacent to each other and the second state may correspond to an extended state in which the first housing 510 and the second housing 520 are disposed in a direction to be spaced apart from each other.

The electronic device 500 including the rollable display 530 according to an embodiment may include a wireless charging integrated circuit (“IC”) 550 disposed inside the first housing 510 or the second housing 520 and capable of receiving power from outside, a battery 540 disposed inside the first housing 510 or the second housing 520 and charged with at least a portion of the power received through the wireless charging IC 550, a drive module 560 configured to generate drive power for movement between the first housing 510 and the second housing 520 by using power received from the wireless charging IC 550 or the battery 540, and/or at least one processor 570.

A first circuit board may be provided inside the first housing 510 according to an embodiment and a second circuit board may be provided inside the second housing 520. The battery 540 according to an embodiment may be disposed inside the second housing 520 and electrically connected to the second circuit board.

The wireless charging IC 550 according to an embodiment may wiredly receive power from the outside through a port or may be electrically connected to an antenna 551 (e.g., a charging coil) for wirelessly receiving power and wirelessly receive power from outside through the antenna 551. For example, in a state in which the electronic device 500 wirelessly receives power through the antenna 551, a large amount of heat may be generated in the antenna 551. In a case where power is wirelessly received from outside, the wireless charging IC 550 may provide the received power to the drive circuit for providing power to the drive module 560 and a power circuit provided on the first circuit board or the second circuit board and charge the battery 540 with at least a portion of the received power.

In addition, in a case where power is wirelessly received from outside, the wireless charging IC 550 according to an embodiment may transmit, to the at least one processor 570, a signal related to wireless reception of power from outside. The wireless charging IC 550 according to an embodiment may receive a upper limit current value from the at least one processor 570 and restrict a size of a current to be received from the outside, based on the receive upper limit current value. For example, the wireless charging IC 550 may restrict the size of the current to be received by the wireless charging IC 550 or the current for charging the battery to be less than or equal to the upper limit current value received from the at least one processor 570.

The drive module 560 according to an embodiment may include a drive source (e.g., a motor), a drive gear, and a drive circuit. The drive module 560 may control an operation of the drive source based on a drive signal received from the at least one processor 570 to generate relative movement between the first housing 510 and the second housing 520. For example, the at least one processor 570 may transmit a drive signal to the drive module 560, based on a sensing result of a distance sensor 580 for sensing a moving distance between the first housing 510 and the second housing 520.

The electronic device 500 including the rollable display 530 according to an embodiment may further include a temperature sensor 541 disposed inside the first housing 510 or the second housing 520 and sensing an internal temperature of the electronic device 500 or a temperature of the battery 540. The temperature sensor 541 according to an embodiment may be disposed adjacent to the battery 540 disposed inside the second housing 520 to sense a temperature of the battery 540.

An operation of the at least one processor 570 according to an embodiment may be described below.

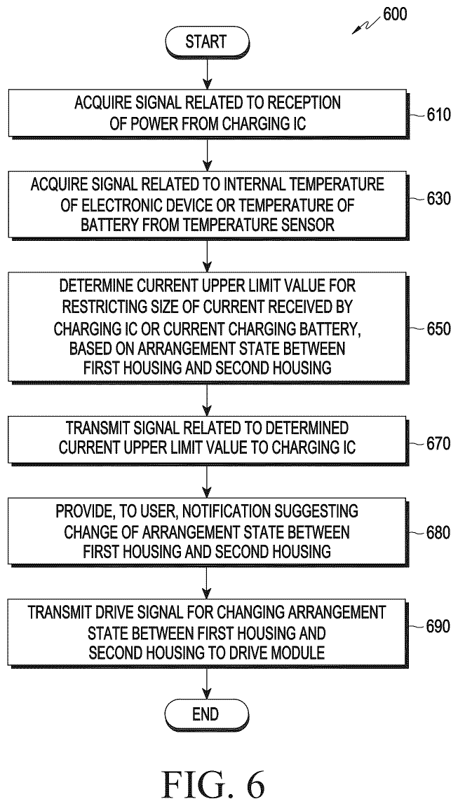

FIG. 6 is a flowchart illustrating a method for operating an electronic device (e.g., the at least one processor 530 in FIG. 5) including a rollable display according to an embodiment of the disclosure.

Referring to FIG. 6, in operation 610, the electronic device (e.g., the at least one processor 530 in FIG. 5) according to an embodiment may acquire, from a wireless charging IC, a signal related to reception of power from outside. The electronic device may determine whether the electronic device enters a charging state in which power is wiredly or wirelessly received from outside according to reception of the signal related to reception of power from outside from the wireless charging IC.

In operation 650, the electronic device according to an embodiment may determine, in a case wherein a case where the signal related to reception of power from outside is acquired, a upper limit current value for restricting an amount of a current to be received from the wireless charging IC (first current) or an amount of a current for charging the battery (second current), based on the arrangement state between the first housing and the second housing (i.e. the slide-in state and the slide-out state).

In operation 650, the electronic device according to an embodiment may determine, in a case where the signal related to reception of power from outside is acquired, a upper limit current value for restricting an amount of a current to be received from the wireless charging IC or an amount of a current for charging the battery, based on the arrangement state between the first housing and the second housing.

Specifically, the electronic device according to an embodiment may configure, as at least a portion of the operation of configuring the upper limit current value, a upper limit current value in a first state in which the second housing moves in a first direction with respect to the first housing, as a first current (e.g., lₘ) and a upper limit current value in a second state in which the second housing moves in a second direction with respect to the first housing, as a second current (e.g., l_{M}). Here, an amount of the first current may be configured to be smaller than a size of the second current. The electronic device may increase a charging speed of the battery by configuring the upper limit current value as the second current having an amount relatively greater in the second state in which the second housing moves in the second direction with respect to the first housing so as to have a relatively increased volume. On the other hand, the electronic device may prevent a temperature of the battery from increasing due to heat generation by charging by configuring the upper limit current value as the first current having an amount relatively smaller in the first state in which the second housing moves in the first direction with respect to the first housing so as to have a relatively reduced volume.

Furthermore, in operation 630, the electronic device according to an embodiment may acquire, in a case where the signal related to reception of power from outside is received, a signal related to an internal temperature of the electronic device or a temperature of the battery from the temperature sensor. For example, when the signal related to an internal temperature of the electronic device or a temperature of the battery is received from the temperature sensor, the electronic device may determine the upper limit current value based on the arrangement state between the first housing and the second housing and/or the internal temperature or the temperature of the battery.

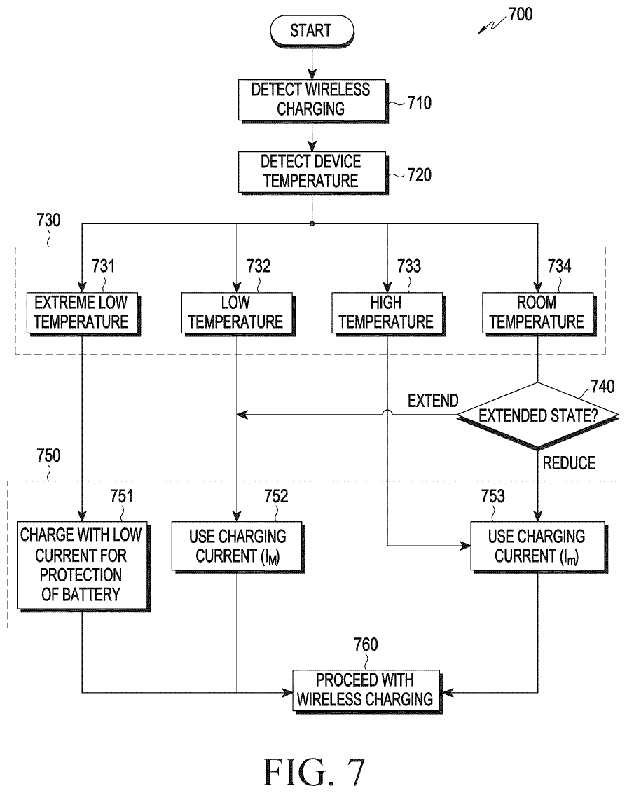

FIG. 7 is a flowchart illustrating a method for determining an upper limit current value of an electronic device (e.g., the at least one processor 530 in FIG. 5) including a rollable display according to an embodiment of the disclosure.

Referring to FIG. 7, the electronic device according to an embodiment may determine an upper limit current value by dividing temperature sections as follows for efficient battery charging.

In operation 710, the electronic device according to an embodiment may detect, in a case where a signal related to reception of power from outside is acquired from the wireless charging IC, that the electronic device is in a charging state. In an embodiment, the electronic device may detect, in a case wherein a case where a signal related to reception of power from outside through the antenna is acquired from the wireless charging IC, a wireless charging state of the electronic device.

Furthermore, in operation 720, the electronic device according to an embodiment may acquire a signal related to at least one of an internal temperature of the electronic device or a temperature of the battery from the temperature sensor. In addition, as at least a portion of an operation of determining an upper limit current value (e.g., operation 650 in FIG. 6), in operation 730, the electronic device may divide the internal temperature of the electronic device or the temperature of the battery into multiple temperature sections and in operation 750, may determine an upper limit current value, based on the arrangement state between the first housing and the second housing and the received signal related to the internal temperature of the electronic device or the temperature of the battery.

Specifically, in a case where the internal temperature of the electronic device or the temperature of the battery is in a room temperature range (10 to 30° C.) in operation 734, the electronic device according to an embodiment may detect, in operation 740, an arrangement state between the first housing and the second housing, and may configure, in a case where the detected arrangement state corresponds to the second state (extended state), in operation 752, the upper limit current value as l_{M}. Here, l_{M} is a maximum charging current supportable by the electronic device and may be configured differently depending on the type and/or capacity of the battery, the pattern and/or efficiency of the wireless charging antenna, etc.

In addition, the electronic device according to an embodiment may configure, in a case where the detected arrangement state corresponds to the first state (reduced state), in operation 753, the upper limit current value as lₘ.

For example, the value of lₘ may be determined by the equation below, based on a difference in heat dissipation performance between the extended state and the reduced state of the first housing and the second housing and IM. Qout is an amount of heat transfer in the expended state between the first housing and the second housing, and Qin is an amount of heat transfer in the reduced state between the first housing and the second housing.

$${l}_{m} = \frac{{Q}_{in}}{{Q}_{out}} * {l}_{M} \qquad [ Equation 1 ]$$

Therefore, depending on the arrangement state between the first housing and the second housing, the upper limit current value for restricting the size of the current to be received from the wireless charging IC or the current for charging the battery is differentiated to efficiently performing charging even in the reduced state of the first housing and the second housing without entering heat limit control.

In a case where the electronic device or the battery is in a low temperature range (0 to 10° C.) in operation 732, the electronic device may configure, in operation 752, the upper limit current value as l_{M}. In a case where the internal temperature of the electronic device or the temperature of the battery is relatively low, the temperature of the electronic device or battery is relatively low even in the reduced state of the first housing and the second housing, and thus even in case of charging with a relatively increased current, it may take a long time for the battery temperature to rise. Accordingly, the electronic device may quickly charge the battery by configuring the upper limit current value as l_{M}.

However, even if the electronic device or the battery starts charging at a low temperature, the temperature of the electronic device or the battery may increase as charging progresses. The electronic device according to an embodiment may continuously receive the temperature of the battery or the inside of the electronic device sensed by a temperature sensor. For example, in a case where the temperature of the battery or the inside of the electronic device rises, leaving the low temperature range and entering the room temperature range, the upper limit current value may be reduced to lₘ in the reduced state of the first housing and the second housing as described above.

Additionally, in a case where the internal temperature of the electronic device or the temperature of the battery is in an extremely low temperature range (up to 0° C.) below zero in operation 731, the electronic device according to an embodiment may perform charging at a low current to protect the battery in operation 751. In a case where the internal temperature of the electronic device or the temperature of the battery is in the extremely low temperature range, the reaction speed of the battery decreases, and thus there is a risk of battery burnout when charging the battery with a high charging current. Furthermore, in a case where the internal temperature of the electronic device or the temperature of the battery rises to the low temperature range or the room temperature range, the electronic device according to an embodiment may charge the battery with a normal charging current (l_{M} or lₘ). Here, a magnitude of the low current for protection of the battery may be preconfigured depending on characteristics of the battery and may be configured as a value smaller than lₘ.

In a case where the internal temperature of the electronic device or the temperature of the battery is in a high temperature range (30° C. or more) in operation 733, the electronic device may configure the upper limit current value as lₘ regardless of the extended state or the reduced state of the first housing and the second housing. In a case where the internal temperature of the electronic device or the temperature of the battery is in the high temperature range, the temperature of the electronic device or battery has already risen high, and when the battery is charged with a high current, heat limit control may be entered within a short period of time. Therefore, the upper limit current value may be configured as lₘ regardless of the extended state or the reduced state of the first housing and the second housing. Even in this case, if the internal temperature of the electronic device or the temperature of the battery decreases and leaves the high temperature range and enters the room temperature range, the upper limit current value may be increased to l_{M} in the extended state of the first housing and the second housing.

In operation 760, the electronic device according to an embodiment may proceed wireless charging of the electronic device or the battery, based on the upper limit current value configured based on the internal temperature of the electronic device or the battery and/or the arrangement state between the first housing and the second housing.

Referring to FIG. 6 again, the electronic device according to an embodiment may transmit, in operation 670, a signal related to the determined upper limit current value to the wireless charging IC. The wireless charging IC according to an embodiment may charge the electronic device or the battery so as not to exceed the upper limit current value, based on the received upper limit current value.

Generally, the electronic device may be capable of quick charging by increasing the upper limit current value in the extended state of the first housing and the second housing. Accordingly, the electronic device may guide the user to extend the first housing and the second housing.

In a case where the arrangement state between the first housing and the second housing is in the reduced state when the signal related to reception of power from outside is acquired, the electronic device according to an embodiment may provide, in operation 680, a notification suggesting a change to the extended state to the user.

In operation 690, the electronic device according to an embodiment may transmit a drive signal for changing the arrangement state between the first housing and the second housing to the drive module. In an embodiment, the electronic device may transmit a drive signal to the drive module, based on a user input in response to the notification indicating the change to the extended state.

In another embodiment, in a case where there is no user input (e.g., an input restricting the change to the extended state) in response to the operation of providing the notification suggesting a change to the extended state in operation 680 or without performing the operation of providing the notification suggesting a change to the extended state of operation 680, the electronic device may transmit a drive signal to the drive module.

For example, in a case where the acquired signal related to reception of power from outside corresponds to a signal indicating of wireless reception through an antenna, the electronic device may automatically transmit a drive signal for changing the arrangement state between the first housing and the second housing to the drive module. Here, the drive signal may correspond to a signal for driving the arrangement state between the first housing and the second housing to change to the second state in which the second housing is drawn out from the inside of the first housing.

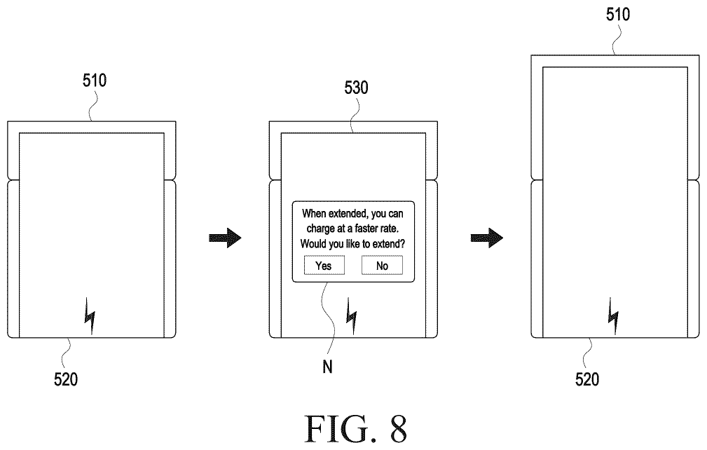

FIG. 8 is an exemplary view illustrating an operation of providing a notification and changing an extended state of an electronic device including a rollable display according to an embodiment of the disclosure.

Referring to FIG. 8, in a case where the signal related to reception of power from outside is acquired, the electronic device according to an embodiment may provide a notification N suggesting a change of the arrangement state between the first housing 510 and the second housing 520 based on the signal related to reception of power.

In a case where the arrangement state between the first housing 510 and the second housing 520 is in the first state in which the second housing 520 moves in the first direction with respect to the first housing 510 to be reduced, the electronic device according to an embodiment may provide, as at least a portion of the operation of providing the notification (e.g., operation 680 in FIG. 6), a notification N suggesting a change to the second state in which the second housing 520 moves in the second direction with respect to the first housing 510. Here, the notification may be a pop-up notification N displayed on a display (e.g., the rollable display 530 in FIG. 5) or a notification that generates visual, auditory, or tactile stimulation to the user.

Referring to FIG. 6 again, in a case where the arrangement state between the first housing and the second housing is in the first state (e.g., the reduced state) in which the second housing moves in the first direction with respect to the first housing to be reduced, the electronic device according to an embodiment may, as at least a portion of the operation of configuring the upper limit current value in operation 650, the upper limit current value as a first current. Furthermore, the electronic device may compare a size of the first current with a size of a second current that will be configured as the upper limit current value when the arrangement state between the first housing and the second housing is changed to the second state (e.g., the extended state).

As at least a portion of the operation of providing a notification in operation 680, the electronic device may provide a notification suggesting a change to the second state based on a result of comparing the sizes between the first current and the second current. For example, in a case where the magnitude of the second current, which is the upper limit current value when the arrangement state between the first housing and the second housing is in the second state, is greater than the magnitude of the first current, which is the upper limit current value when the arrangement state between the first housing and the second housing is in the first state, the electronic device may provide a notification suggesting a change to the second state.

The electronic device according to an embodiment may acquire a signal related to the internal temperature of the electronic device or the temperature of the battery from the temperature sensor in operation 630, and provide a notification suggesting a change of the arrangement state between the first housing and the second housing to the user, based on the acquired signal related to the internal temperature of the electronic device or the temperature of the battery in operation 680.

For example, in a case where the internal temperature of the electronic device or the temperature of the battery is in the high temperature range, the electronic device may provide a notification to the user for suggesting a change the arrangement state between the first housing and the second housing to the second state in which the second housing moves in the second direction with respect to the first housing to be extended. Accordingly, by improving the heat dissipation performance of the electronic device, the internal temperature of the electronic device or the temperature of the battery may be reduced.

In addition, for example, in a case where the internal temperature of the electronic device or the temperature of the battery is in the room temperature range, the electronic device may provide a notification to the user for suggesting a change the arrangement state between the first housing and the second housing to the second state in which the second housing moves in the second direction with respect to the first housing to be extended. Accordingly, by increasing the upper limit current value that limits the magnitude of a current to be received by the wireless charging IC of the electronic device or a current for charging the battery from lₘ to l_{M}, the charging speed may be improved.

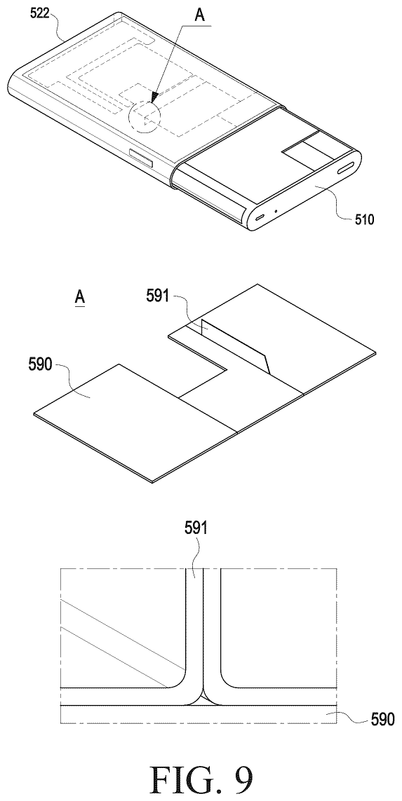

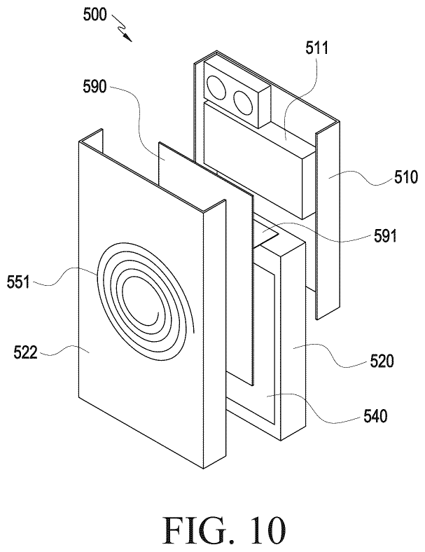

FIG. 9 is an exemplary view illustrating an electronic device 500 including a rollable display 530 having a heat dissipation plate 590 according to an embodiment of the disclosure. FIG. 10 is an exploded perspective view illustrating an electronic device 500 including a rollable display 530 having a heat dissipation plate 590 according to an embodiment of the disclosure.

Referring to FIGS. 9 and 10, the electronic device 500 according to an embodiment may increase an amount of heat dissipation by using the heat dissipation plate 590. Accordingly, the amount of heat dissipation of the electronic device 500 increases, thereby increasing the upper limit current value that restricts the charging current of the electronic device 500 or the battery 540.

In the electronic device 500 according to an embodiment, a book cover 522 may be fixedly coupled to the second housing 520, and cover at least a portion of the first housing 510 that relatively moves with respect to the second housing 520. The book cover 522 may be include an area that the user holds with his or her hand.

The heat dissipation plate 590 is made of a material with a relatively high heat transfer rate, and an amount of heat transfer may be increased by thermally connecting the book cover 522 and the second housing 520. The heat dissipation plate 590 may be disposed on a rear surface of the book cover 522 on which an antenna 551 for wireless charging is mounted. The heat dissipation plate 590 may spread the heat of the antenna 551 generated during wireless charging to the entire surface of the book cover 522.

However, since a size of the book cover 522 is reduced compared to a conventional bar type when the electronic device 500 is in the reduced state, a sufficient heat dissipation effect may not be secured. Accordingly, the heat dissipation plate 590 may extend in a plane direction between the book cover 522 and the second housing 520 and contact each of the book cover 522 and the second housing 520, and the heat dissipation plate 590 may include a lateral wall 591 bent and extended in a direction intersecting the extended planar direction so as to come in contact with at least two surfaces of the second housing 520.

In an embodiment, the heat dissipation plate 590 may include multiple sheets extending in the plane direction, and at least one sheet configuring a lower surface may have a shape bent to define the lateral wall 591. For example, the lateral wall of the heat dissipation plate 590 may be disposed to contact a lateral surface of the battery 540 or the second housing 520 in which the battery 540 is mounted, and thermally connect the book cover 522 and the second housing 520 so as to increase the amount of heat transfer. For example, the lateral wall of the heat dissipation plate 590 may be in contact with a first circuit board 511 fixed to the first housing 510 in the first state in which the first housing 510 and the second housing 520 are reduced and dissipate heat generated from the first circuit board 511.

An electronic device 500 according to an embodiment may include a first housing 510, a second housing 520 movable with respect to the first housing 510, a rollable display 530 which is at least partially fixed to a surface of the second housing 520 and inserted into an inside of the first housing 510 in a slide-in state of the second housing or drawn out from the inside of the first housing 510 in a slide-out state of the second housing, a wireless charging IC 550 in the first housing 510 or the second housing 520 and configured to be capable of receiving power from an outside, a battery 540 in the first housing 510 or the second housing 520 and configured to be charged with power from the outside through the wireless charging IC 550, and at least one processor 570configured to, based on the slide-in state or the slide-out state of the second housing 520 with respect to the first housing 510, determine an amount of a current to be received from outside through the wireless charging IC 550 or an amount of a current for charging the battery 540, wherein the current to be received from the outside through the wireless charging IC 550 is different from the current for charging the battery 540, and transmit a signal related to the current to be received from the outside through the wireless charging IC 550 or the current for charging the battery 540 to the wireless charging IC 550.

According to an embodiment, an antenna electrically connected to the wireless charging IC 550 and configured to wirelessly receive power may be further included and the wireless charging IC 550 may transmit or receive power wirelessly through the antenna.

According to an embodiment, the at least one processor 570 may be configured to determine an upper limit current value of the amount of the current to be received from outside through the wireless charging IC 550 and the amount of the current for charging the battery 540, and transmit a signal related to the upper limit current value to the wireless charging IC 550.

According to an embodiment, in a state in which the second housing 520 is in the slide-in state with respect to the first housing 510, the amount of the current to be received from outside through the wireless charging IC 550 or the amount of the current for charging the battery 540 is a first current. In a state in which the second housing 520 is in the slide-out state with respect to the first housing 510, the amount of the current to be received from outside through the wireless charging IC 550 or the amount of the current for charging the battery 540 is a second current. The amount of the first current may be less than of the amount of the second current.

According to an embodiment, a temperature sensor 541 inside the first housing 510 or the second housing 520 and sensing an internal temperature of the electronic device 500 or a temperature of the battery 540 may be further included, and the at least one processor 570 may be configured to acquire a signal related to the internal temperature of the electronic device 500 or the temperature of the battery 540 from the temperature sensor 541 and based on the acquired signal related to the internal temperature of the electronic device 500 or the temperature of the battery 540 and the slide-in state or slide-out state of the second housing 520 with respect to the first housing 510, determine the current to be received from the outside through the wireless charging IC 550 or the current for charging the battery 540.

According to an embodiment, in a case where the internal temperature of the electronic device 500 or the temperature of the battery 540 is equal to or greater than a preconfigured first temperature and less than a preconfigured second temperature, the at least one processor 570 may be further configured to configure the amount of the current to be received from outside through the wireless charging IC 550 or the amount of the current for charging the battery 540 to be the first current or the second current based on the slide-in state or slide-out state of the second housing 520 with respect to the first housing 510, and the amount of the first current may less than the amount of the second current.

According to an embodiment, in a case where the internal temperature of the electronic device 500 or the temperature of the battery 540 is less than the preconfigured first temperature, the at least one processor 570 may be further configured to configure the current to be received from outside through the wireless charging IC 550 or the current for charging the battery 540 to be the second current.

According to an embodiment, in a case where the internal temperature of the electronic device 500 or the temperature of the battery 540 is equal to or greater than the preconfigured second temperature, the at least one processor 570 may be further configured to configure the current to be received from outside through the wireless charging IC 550 or the current for charging the battery 540 to be the first current.

According to an embodiment, a temperature sensor 541 inside the first housing 510 or the second housing 520 and configured to sense an internal temperature of the electronic device 500 or a temperature of the battery 540 may be further included, and the at least one processor 570 may be configured to acquire a signal related to the internal temperature of the electronic device 500 or the temperature of the battery 540 from the temperature sensor 541 and provide, to the user, a notification suggesting a change of the slide-in state or slide-out state of the second housing 520 with respect to the first housing 510 based on the signal related to the internal temperature of the electronic device 500 or the temperature of the battery 540.

According to an embodiment, in a state in which the second housing 520 is in the slide-in state with respect to the first housing 510, the at least one processor 570 may be further configured to provide a notification suggesting the user to change the second housing 520 from the slide-in state to the slide-out state respect to the first housing 510.

According to an embodiment, in a state in which the second housing 520 is in the slide-in state with respect to the first housing 510, the at leats one processor 570 may be further configured to configure the amount of the current to be received from outside through the wireless charging IC 550 or the current for charging the battery 540 to be a first current, compare an amount of the first current with an amount of a second current, the second current being the amount of the current to be received from outside through the wireless charging IC or the amount of the current for charging the battery when the second housing 520 is changed from the slide-in state to the slide-out state with respect to the first housing 510, and provide a notification suggesting the user to change the second housing 520 from the slide-in state to the slide-out state with respect to the first housing 510, based on a comparison result of the amount of the first current and the amount of the second current.

According to an embodiment, a drive module 560 configured to generate drive power for movement between the first housing 510 and the second housing 520 may be further included, and the at least one processor 570 may be configured to, in a case where a signal related to the reception of power from outside is acquired, transmit, to the drive module 560, a drive signal configured to change the second housing 520 from the slide-in state to the slide-out state with respect to the first housing 510 or change the second housing 520 from the slide-out state to the slide-in state with respect to the first housing 510.

According to an embodiment, the battery 540 may further include a heat dissipation plate 590 inside the second housing 520, extending in a planar direction and between the antenna and the battery 540, and the heat dissipation plate 590 may be bent and extended in a direction intersecting the planar direction and contacting at least two surfaces of the second housing 520.

According to an embodiment of the disclosure, a method 600 for operation an electronic device 500 may include an operation 650 of determining, based on the slide-in or slide-out state of the second housing 520 with respect to the first housing 510, an amount of a current to be received from outside through the wireless charging IC 550 or an amount of a current for charging the battery 540, wherein the current to be received from the outside through the wireless charging IC 550 is different from the current for charging the battery 540, and transmitting a signal related to the current to be received from the outside through the wireless charging IC 5550 or the current for charging the battery 540 to the wireless charging IC 550.

According to an embodiment, the operation 650 of determining a size of the current to be received from outside through the wireless charging IC 550 or a size of the current for charging the battery 540 to be different from each other may further include an operation 670 of determining, based on the slide-in state or the slide-out state of the second housing 520 with respect to the first housing 510, an upper limit current value for restricting the size of the current to be received from outside through the wireless charging IC 550 and the current for charging the battery 540, and transmitting a signal related to the determined upper limit current value to the wireless charging IC 550.

According to an embodiment, in the operation 650 of determining a size of the current to be received from outside through the wireless charging IC 550 or a size of the current for charging the battery 540 to be different from each other may include an operation, the size of the current to be received from outside through the wireless charging IC 550 or the current for charging the battery 540 may be configured to be a first current in the slide-in state of the second housing 520 with respect to the first housing 510 and configuring the size of the current to be received from outside through the wireless charging IC 550 or the current for charging the battery 540 to be a second current in the slide-out state of the second housing 520 with respect to the first housing 510, and the first current may be configured to have a size smaller than a size of the second current.

According to an embodiment, an operation 630 of acquiring a signal related to the internal temperature of the electronic device 500 or the temperature of the battery 540 from a temperature sensor 541 may be further included, and in the operation 650 of determining an amount of the current to be received from outside through the wireless charging IC 550 or a size of the current for charging the battery 540 to be different from each other may be based on the acquired signal related to the internal temperature of the electronic device 500 or the temperature of the battery 540 and the slide-in or the slide-out state of the second housing 520 with respect to the first housing 510.

According to an embodiment, as at least a portion of the operation 650 of determining a size of the current to be received from outside through the wireless charging IC 550 or a size of the current for charging the battery 540 to be different from each other, in a case where the internal temperature of the electronic device 500 or the temperature of the battery 540 is equal to or greater than a preconfigured first temperature and less than a preconfigured second temperature, the size of the current to be received from outside through the wireless charging IC 550 or the current for charging the battery 540 may be configured to be the first current or the second current, based on the slide-in or slide-out state of the second housing 520 with respect to the first housing 510, and the first current may be configured to have a size smaller than a size of the second current.

According to an embodiment, an operation 630 of acquiring a signal related to the internal temperature of the electronic device 500 or the temperature of the battery 540 from a temperature sensor 541, and in a case where the signal related to the reception of power from outside is acquired, an operation 680 of providing, to the user, a notification suggesting a change of the slide-in or slide-out state of the second housing 520 with respect to the first housing 510 may be further included.

According to an embodiment, as at least a portion of the operation 680 of providing the notification, in a case where the second housing 520 is in the slide-in state with respect to the first housing 510, a notification suggesting a change to the slide-out state of the second housing 520 with respect to the first housing 510 may be provided.

While example embodiments of the disclosure have been shown and described, the disclosure is not limited to the aforementioned specific embodiments, and it is to be understood that various modifications may be made by those having ordinary skill in the technical field to which the disclosure belongs, without departing from the gist of the disclosure as claimed by the appended claims. Further, it is intended that such modifications are not to be interpreted independently from the technical idea or prospect of the disclosure.

What is claimed is:

1. An electronic device comprising:
a first housing;
a second housing movable with respect to the first housing;
a rollable display at least partially fixed to the second housing and configured to be inserted into an inside of the first housing in a slide-in state of the second housing or drawn out from the inside of the first housing in a slide-out state of the second housing;
a wireless charging integrated circuit (“IC”) in the first housing or the second housing and configured to be capable of receiving power from an outside;
a battery in the first housing or the second housing and configured to be charged with power received from the outside through the wireless charging IC; and
at least one processor is configured to:
based on the slide-in state or the slide-out state of the second housing with respect to the first housing, determine an amount of a current to be received from the outside through the wireless charging IC or an amount of a current for charging the battery, wherein the current to be received from the outside through the wireless charging IC is different from the current for charging the battery; and
transmit a signal related to the current to be received from the outside through the wireless charging IC or the current for charging the battery to the wireless charging IC.

2. The electronic device of claim 1, further comprising an antenna electrically connected to the wireless charging IC and configured to wirelessly receive power, and
wherein the wireless charging IC is further configured to wirelessly receive power through the antenna.

3. The electronic device of claim 1, wherein the at least one processor is further configured to:
based on the slide-in or slide-out state of the second housing with respect to the first housing, determine an upper limit current value of the amount of the current to be received from outside through the wireless charging IC or the amount of the current for charging the battery; and
transmit a signal related to the upper limit current value to the wireless charging IC.

4. The electronic device of claim 1, wherein in a state in which the second housing is in the slide-in state with respect to the first housing, the amount of the current to be received from outside through the wireless charging IC or the amount of the current for charging the battery is a first current,
wherein in a state in which the second housing is in the slide-out state with respect to the first housing, the amount of the current to be received from outside through the wireless charging IC or the amount of the current for charging the battery is a second current, and
wherein the amount of the first current is less than the amount of the second current.

5. The electronic device of claim 1, further comprising a temperature sensor inside the first housing or the second housing and configured to sense an internal temperature of the electronic device or a temperature of the battery,
wherein the at least one processor is further configured to:
acquire a signal related to the internal temperature of the electronic device or the temperature of the battery from the temperature sensor; and
based on the acquired signal related to the internal temperature of the electronic device or the temperature of the battery and the slide-in state or the slide-out state of the second housing with respect to the first housing, determine the current to be received from the outside through the wireless charging IC or the current for charging the battery.

6. The electronic device of claim 5, wherein in a state in which the internal temperature of the electronic device or the temperature of the battery is equal to or greater than a preconfigured first temperature and less than a preconfigured second temperature, the at least one processor is further configured to configure the amount of the current to be received from outside through the wireless charging IC or the amount of the current for charging the battery to have a first current or a second current based on the slide-in state or the slide-out state of the second housing with respect to the first housing, and
wherein the amount of the first current is less than the amount of the second current.

7. The electronic device of claim 6, wherein in a state in which the internal temperature of the electronic device or the temperature of the battery is less than the preconfigured first temperature, the at least one processor is further configured to configure the current to be received from outside through the wireless charging IC or the current for charging the battery to be the second current.

8. The electronic device of claim 6, wherein in a state in which the internal temperature of the electronic device or the temperature of the battery is equal to or greater than the preconfigured second temperature, the at least one processor is further configured to configure the current to be received from outside through the wireless charging IC or the current for charging the battery to be the first current.

9. The electronic device of claim 1, further comprising a temperature sensor inside the first housing or the second housing and configured to sense an internal temperature of the electronic device or a temperature of the battery,
wherein the at least one processor is further configured to:
acquire a signal related to the internal temperature of the electronic device or the temperature of the battery from the temperature sensor; and
provide, to a user, a notification suggesting a change of the slide-in state or the slide-out state of the second housing with respect to the first housing based on the signal related to the internal temperature of the electronic device or the temperature of the battery.

10. The electronic device of claim 9, wherein in a state in which the second housing is in the slide-in state with respect to the first housing, the at least one processor is further configured to provide a notification suggesting the user to change the second housing from the slide-in state to the slide-out state respect to the first housing.

11. The electronic device of claim 10, wherein in a state in which the second housing is in the slide-in state with respect to the first housing, the at least one processor is further configured to:
configure the amount of the current to be received from outside through the wireless charging IC or the current for charging the battery to be a first current;
compare an amount of the first current with an amount of a second current, the second current being the amount of the current to be received from outside through the wireless charging IC or the amount of the current for charging the battery when the second housing is changed from the slide-in state to the slide-out state with respect to the first housing; and
provide the notification suggesting the user to change the second housing from the slide-in state to the slide-out state with respect to the first housing, based on a comparison result of the amount of the first current and the amount of the second current.

12. The electronic device of claim 2, further comprising a drive module configured to generate drive power for movement between the first housing and the second housing,
wherein the at least one processor is further configured to, in a state in which a signal related to the reception of power from outside is acquired, transmit, to the drive module, a drive signal configured to change the second housing from the slide-in state to the slide-out state with respect to the first housing or change the second housing from the slide-out state to the slide-in state with respect to the first housing.

13. The electronic device of claim 2, wherein the battery is inside the second housing, and the electronic device further comprises a heat dissipation plate extending in a planar direction and disposed between the antenna and the battery, and
wherein the heat dissipation plate is bent and extended in a direction intersecting the planar direction and contacting at least two surfaces of the second housing.

14. A method for operating an electronic device comprising a first housing, a second housing movable with respect to the first housing, a rollable display partially fixed to the second housing and configured to be inserted into an inside of the first housing in a slide-in state of the second housing or drawn out from the inside of the first housing in a slide-out state of the second housing, a wireless charging IC configured to be capable of receiving power from an outside, and a battery configured to be charged with at least a portion of power received through the wireless charging IC, the method comprising:
based on the slide-in state or the slide-out state of the second housing with respect to the first housing, determining an amount of a current to be received from the outside through the wireless charging IC or an amount of a current for charging the battery, wherein the current to be received from the outside through the wireless charging IC is different from the current for charging the battery; and
transmitting a signal related to the current to be received from the outside through the wireless charging IC or the current for charging the battery to the wireless charging IC.

15. The method of claim 14, further comprising acquiring a signal related to an internal temperature of the electronic device or a temperature of the battery from a temperature sensor,
wherein the determining of the amount of the current to be received from outside through the wireless charging IC or the amount of the current for charging the battery is based on the acquired signal related to the internal temperature of the electronic device or the temperature of the battery and the slide-in state or the slide-out state of the second housing with respect to the first housing.
